(19) United States
(12) Patent Application Publication
(10) Pub. No.: US 2003/0038379 A1
(43) Pub. Date: Feb. 27, 2003

(54) Laminate film for mounting electronic devices and film carrier tape for mounting electronic devices

(75) Inventors: Shuichi Kawasaki, Shinagawa-ku (JP); Hiromu Terada, Shinagawa-ku (JP)

Correspondence Address: SUGHRUE MION, PLLC, 2100 PENNSYLVANIA AVENUE, N.W., WASHINGTON, DC, 20037, US

(73) Assignee: MITSUI MINING & SMELTING CO., LTD.

(21) Appl. No.: 10/219,487

(22) Filed: Aug. 16, 2002

(30) Foreign Application Priority Data
Aug. 20, 2001 (JP) 2001-249499

(51) Int. Cl. H01L 23/495; H01L 23/48

(52) U.S. Cl. 257/783; 257/674; 257/690

(57) ABSTRACT

A laminate film for mounting electronic devices includes a conductive layer and an insulating film which are bonded through thermocompression bonding. The coefficient of thermal expansion of the insulating film along the width direction thereof is substantially equal to or higher than that of the conductive layer along the width direction thereof.

### BACKGROUND OF THE INVENTION

1. Field of the Invention

The present invention relates to a laminate film for use in a film carrier tape for mounting electronic devices such as ICs or LSIs, and to a film carrier tape using the same.

2. Description of the Related Art

Development of the electronic industries has drastically increased demand for printed wiring boards for mounting electronic devices such as integrated circuits (ICs) and large-scale integrated circuits (LSIs). Also, electronic equipment has been required to exhibit reduced size and weight and enhanced performance. Under the circumstances, TAB tapes, T-BGA tapes, ASIC tapes, etc. have recently been employed for mounting these electronic devices. Particularly, with a tendency toward reduction in size and weight of electronic equipment, a film carrier tape for mounting electronic devices which includes a substrate substantially equal in size to the electronic devices to be mounted and having external connection terminals arranged on substantially the entire surface thereof has been used more often in order to mount electronic devices at higher density and to enhance reliability of electronic devices. Such a film carrier tape has been used for, for example, a chip size package (CSP), a ball grid array (BGA), a μ-ball grid array (μ-BGA), a flip chip (FC), or a quad flat package (QFP).

Such film carrier tape for mounting electronic devices is manufactured from a laminate film of a conductive layer and an insulating layer. The conductive layer is patterned to form wiring patterns. A film carrier tape of a certain type may have, for example, through-holes for wire bonding use, and a solder resist layer for protecting wiring patterns.

This film carrier tape for mounting electronic devices is mounted with electronic devices, such as ICs, such that the electronic devices are mounted directly on the wiring patterns or such that connections to the wiring pattenrs are established through, for example, wire bonding, metal bumps, or solder balls. Subsequently, the electronic devices are molded by use of sealing resin.

Such film carrier tape for mounting electronic devices is manufactured from, for example, a laminate film of a copper foil, and an insulating film bonded through thermocompression bonding via a thermoplastic or thermosetting resin. With the recent tendency toward a reduction in the thickness of a film carrier tape, the thickness of this laminate film to be used has been reduced.

However, a conventional thermocompression-bonding-type laminate film for mounting electronic devices; particularly, a relatively thin laminate film, involves a problem in that the conductive layer of the film warps concavely along the width direction thereof. When such warp occurs, a film carrier tape cannot be transported smoothly or properly in a process for mounting electronic devices on the tape, so that mounting work is adversely affected. In a worse case, electronic devices fail to be mounted on the film carrier tape, thereby raising a serious problem.

### SUMMARY OF THE INVENTION

In view of the foregoing, an object of the present invention is to provide a flat laminate film for mounting electronic devices capable of easily and effectively reducing warp thereof along the width direction thereof, as well as a film carrier tape for mounting electronic devices using the laminate film.

Here, the term “width direction”, which is called as “transverse direction; TD”, refers the direction orthogonal to the longitudinal direction (i.e. machinery direction; MD) of the film carrier tape.

To achieve the above object, the present invention provides a laminate film for mounting electronic devices, comprising a conductive layer and an insulating film bonded through thermocompression bonding, the coefficient of thermal expansion of the insulating film along the width direction of the insulating film being substantially equal to or higher than that of the conductive layer along the width direction of the conductive layer.

The thus-configured laminate film exhibits effective reduction in warpage thereof along the width direction thereof.

The coefficient of thermal expansion(CTE) of the insulating film along the width direction of the insulating film may be 16.0 to 30.0 ppm/° C. In this case, warpage of the laminate film along the width direction of the laminate film can be sufficiently reduced.

The conductive layer may be a copper foil.

The insulating film and the conductive layer may be bonded through thermocompression bonding via a thermoplastic resin layer or a thermosetting resin layer.

The present invention further provides a film carrier tape for mounting electronic devices, comprising the laminate film for mounting electronic devices of the present invention.

Since the laminate film is formed of a conductive layer and an insulating film through thermocompression bonding, no warp occurs along the width direction thereof. Therefore, there can be realized a film carrier tape for mounting electronic devices, which can be transported smoothly, in a process for mounting electronic devices such as ICs, by means of the flat laminate film, and ensures reliable mounting of electronic devices.

### BRIEF DESCRIPTION OF THE DRAWINGS

FIGS. 1A and 1B are views schematically showing the structure of a laminate film for mounting electronic devices according to an embodiment of the present invention, wherein FIG. 1A is a partial, perspective view of the laminate film, and FIG. 1B is a sectional view of the laminate film;

FIG. 2 is a schematic side view showing an example method for manufacturing the laminate film of FIG. 1A;

FIGS. 3A and 3B are views schematically showing the structure of a film carrier tape for mounting electronic devices according to an embodiment of the present invention, wherein FIG. 3A is a plan view of the film carrier tape, and FIG. 3B is a partially sectional view of the film carrier tape;

FIGS. 4A to 4F are partially sectional views showing an example method for manufacturing a film carrier tape for mounting electronic devices according to an embodiment of the present invention;

FIGS. 5A and 5B are views schematically showing the structure of a film carrier tape for mounting electronic devices according to another embodiment of the present invention, wherein FIG. 5A is a plan view of the film carrier tape, and FIG. 5B is a partially sectional view of the film carrier tape;

FIG. 6 is a plan view schematically showing the structure of a film carrier tape for mounting electronic devices according to a further embodiment of the present invention; and

FIG. 7 is a sectional view taken along line A-A′ of FIG. 6.

### DESCRIPTION OF THE PREFERRED EMBODIMENTS

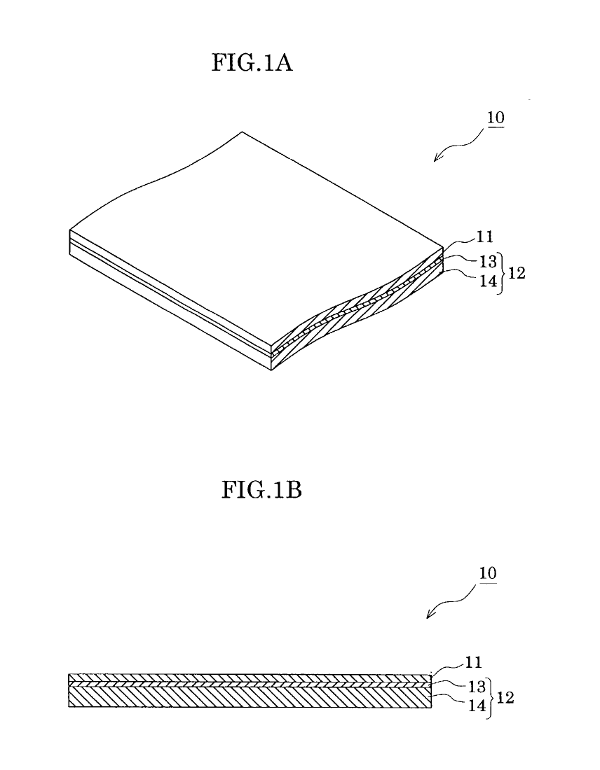

Laminate films for mounting electronic devices and film carrier tapes for mounting electronic devices according to embodiments of the present invention will next be described in detail with reference to the drawings. FIGS. 1A and 1B schematically show the structure of a laminate film for mounting electronic devices according to an embodiment of the present invention, wherein FIG. 1A is a partial, perspective view of the laminate film, and FIG. 1B is a sectional view of the laminate film.

As shown in FIGS. 1A and 1B, a laminate film for mounting electronic devices 10 of the present embodiment includes a conductive layer 11 and an insulating layer 12, which is thermocompression-bonded to the conductive layer 11.

The conductive layer 11 can be formed of, for example, copper, gold, silver, or aluminum, and is commonly formed of a copper foil. No particular limitation is imposed on the copper foil, but, for example, an electro deposited copper foil or a rolled copper foil is preferred in view of etching properties, readiness of handling, etc. The thickness of the conductive layer 11 is generally 1 to 70 μm, preferably 5 to 35 μm. The conductive layer 11 formed of, for example, a copper foil has a coefficient of thermal expansion of 16.5 ppm/° C. along the width direction thereof.

The insulating layer 12 includes an adhesive layer 13 for bonding to the conductive layer 11, and an insulating film 14 on which the adhesive layer 13 is formed. The insulating film 14 may be formed of a flexible, chemical resistant, heat resistant material. Examples of a material for the insulating film 14 include polyimide, polyester, polyamide, polyether-sulfone, and a liquid crystal polymer. Preferably, the material for the insulating film 14 is an aromatic polyimide having a biphenyl skeleton and only aromatic monomer units (e.g., UPILEX, trade name of product from UBE Industries, Ltd.). The thickness of the insulating film 14 is generally 12.5 to 75 μm, preferably 25 to 75 μm. Particularly, in manufacture of a thin laminate film for mounting electronic devices, use of the insulating film 14 having a thickness not greater than 50 μm is preferred.

In the present embodiment, the adhesive layer 13 for bonding the conductive layer 11 and the insulating film 14 is formed of a thermosetting resin, a thermoplastic resin, or any other suitable resin which is flexible and has chemical resistance and heat resistance. The adhesive layer 13 may be formed by applying such a resin directly to the insulating film 14 or by use of an adhesive tape. Examples of this thermosetting resin include epoxy resin materials and polyamide resin materials. Examples of this thermoplastic resin include thermoplastic polyimide resin materials. No particular limitation is imposed on a material for the adhesive layer 13 so long as it can reliably bond the conductive layer 11 and the insulating film 14.

The insulating film 14 and the adhesive layer 13 may have through-holes formed therein beforehand. Examples of such through-holes include sprocket holes used for transporting or positioning a film carrier tape for mounting electronic devices; through-holes for use with solder balls; device holes for use with electronic devices; and through-holes for wire bonding use. For example, in the case where sprocket holes are formed, the conductive layer 11 may be thermocompression-bonded via the adhesive layer 13 to a region of the insulating film 14 other than the opposite side edge regions where the sprocket holes are formed, or to the entire surface of the insulating film 14, including the sprocket hole regions, via the adhesive layer 13.

The insulating film 14 has a coefficient of thermal expansion along the width direction thereof substantially equal to or greater than that of the conductive layer 11. The insulating film 14 formed of, for example, a polyimide film has a coefficient of thermal expansion along the width direction thereof of 16.0 to 30.0 ppm/° C. Preferably, in order to more favorably reduce the warpage of the laminate film for mounting electronic devices 10 along the width direction thereof, the coefficient of thermal expansion of the insulating film 14 along the width direction thereof is 16.5 to 25.0 ppm/° C.

This range of the coefficient of thermal expansion is selected in order to alleviate effectively a problem in that the conductive layer 11 of the laminate film for mounting electronic devices 10 warps concavely along the width direction thereof due to the difference between a dimensional change along the width direction of the conductive layer 11 induced by thermal expansion and that of the insulating film 14 induced by thermal expansion.

The present invention intends to cope with the warp of the laminate film for mounting electronic devices 10 along the width direction thereof, and thus no particular limitation is imposed on a coefficient of thermal expansion along the longitudinal direction. However, conceivably, a similar warping phenomenon is also involved in relation to the longitudinal direction. Therefore, preferably, the coefficient of thermal expansion of the insulating film 14 along the longitudinal direction thereof is substantially equal to or higher than that of the conductive layer 11 along the longitudinal direction thereof.

The present invention may use the insulating film 14 having an appropriate coefficient of thermal expansion along the width direction thereof that is selected in view of the coefficient of thermal expansion of the conductive layer 11 along the width direction thereof and the expansion of the insulating film 14 along the width direction thereof induced by moisture absorption.

Specifically, when the insulating film 14 is to be selected so as to have a coefficient of thermal expansion along the width direction thereof substantially equal to that of the conductive layer 11, it is preferable that the insulating film 14 exhibits substantially no expansion induced by moisture absorption. Selection of this insulating film 14 prevents a problem in that, after thermocompression bonding, the insulating film 14 expands in the width direction due to moisture absorption, thereby causing the conductive layer 11 of the laminate film for mounting electronic devices 10 to warp concavely along the width direction thereof.

In view of the coefficient of thermal expansion of the insulating film 14 along the width direction thereof induced by moisture absorption, preferably, the coefficient of thermal expansion of the insulating film 14 along the width direction thereof is slightly higher than that of the conductive layer 11 along the width direction thereof, for the following reason. Because of selection of a higher expansion coefficient for the insulating film 14, when the laminate film for mounting electronic devices 10 is cooled subsequently to thermocompression bonding, the laminate film 10 warps temporarily along the width direction in such a manner that a central portion of the laminate film 10 displaces upward in FIG. 1B. However, a subsequent expansion of the insulating film 14 induced by moisture absorption induces a predetermined stress within the insulating film 14 in a direction such that the central portion of the laminate film 10 displaces downward in FIG. 1B. As a result, the laminate film 10 becomes flat.

Thus, employment of a coefficient of thermal expansion of the insulating film 14 along the width direction thereof that is equal to or higher than that of the conductive layer 11 along the width direction thereof prevents effectively a problem in that the conductive layer 11 of the laminate film for mounting electronic devices 10 warps concavely.

The adhesive layer 13 for bonding the insulating film 14 and the conductive film 11 generally has a high coefficient of thermal expansion. However, since the adhesive layer 13 is thin as compared with the insulating film 14, the adhesive layer 13 has substantially no effect on warp induced by thermal expansion. However, preferably, the adhesive layer 13 has a coefficient of thermal expansion which is close to that of the insulating film 14 to the greatest extent possible.

Next, an example of a method for manufacturing the above-described laminate film for mounting electronic devices 10 will be described.

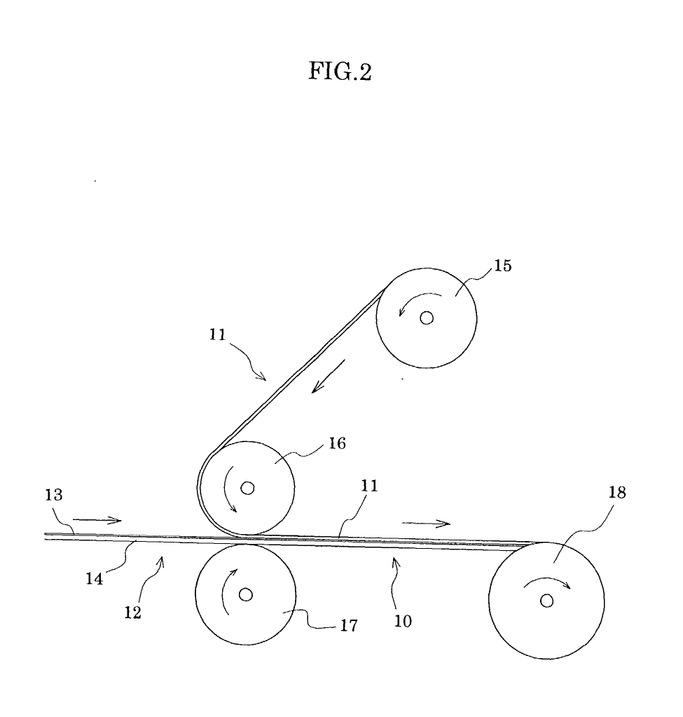

As shown in FIG. 2, the laminate film for mounting electronic devices 10 is manufactured in the following manner. An insulator (insulating layer) 12 composed of the insulating film 14 and the adhesive layer 13 is fed, while a conductor (conductive layer) 11 is unwound from an unwind roller 15. The thus-fed insulator 12 and the thus-unwound conductor 11 are held between thermocompression bonding rollers 16 and 17 while being subjected to respectively predetermined tensions and heated at a constant temperature, whereby the conductor 11 and the insulation film 14 are bonded via the adhesive layer 13 formed of a thermoplastic resin or a thermosetting resin, thereby yielding the laminate film for mounting electronic devices 10. The laminate film 10 is taken up by a take-up roller 18.

Either one or both of the thermocompression bonding rollers 16 and 17 may be heated. Generally, the thermocompression bonding roller 16, which is in contact with the conductor 11, is heated. However, in order to prevent warp, preferably, both of the thermocompression bonding rollers 16 and 17 are heated. When the thermocompression bonding rollers 16 and 17 are both heated, both of them may be heated such that the conductor 11 and the insulator 12 are heated at the same temperature. However, in order to reduce effectively the warpage of the laminate film for mounting electronic devices 10, preferably, the thermocompression bonding roller 17, which is in contact with the insulator 12, is heated such that the insulator 12 is heated at a higher temperature. Notably, the present invention is not limited to this method for manufacturing the laminate film 10.

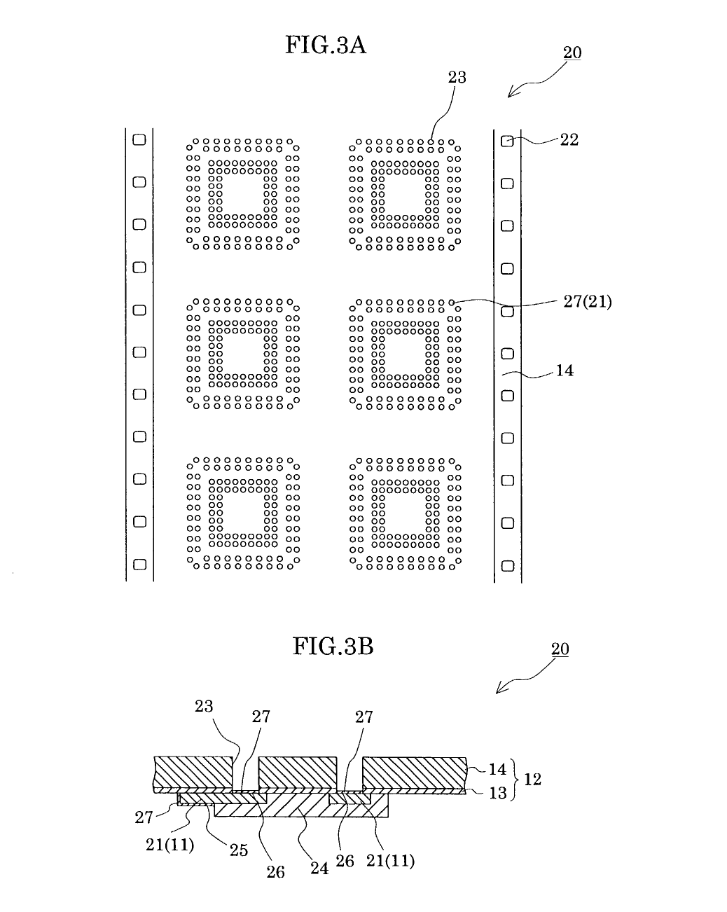

Next will be described a film carrier tape for mounting electronic devices according to an embodiment of the present invention manufactured from the above-described laminate film for mounting electronic devices 10. FIGS. 3A and 3B schematically show the structure of this film carrier tape, wherein FIG. 3A is a plan view of the film carrier tape, and FIG. 3B is a partially sectional view of the film carrier tape.

As shown in FIGS. 3A and 3B, a film carrier tape for mounting electronic devices 20 is a chip size package (CSP)-type film carrier tape which is manufactured from the above-described laminate film for mounting electronic devices 10 and which has a size substantially equal to that of electronic devices to be mounted thereon. A plurality of regions where electronic devices are to be mounted are provided in an array on the film carrier tape 20.

The film carrier tape for mounting electronic devices 20 includes a plurality of wiring patterns 21 formed through patterning of the conductive layer 11, a plurality of sprocket holes 22 formed on widthwise opposite sides of a region where the wiring patterns 21 are formed, and a plurality of through-holes 23 formed in regions where the corresponding wiring patterns 21 are formed. The sprocket holes 22 are used for positioning the film carrier tape 20 when the conductive layer 11 is to be patterned, or for transporting the film carrier tape 20 in the course of mounting electronic devices on the film carrier tape 20.

A solder resist layer 24 is formed on each of the wiring patterns 21 by applying a solder resist solution to the wiring pattern 21 by means of a screen printing process. Portions of the wiring pattern 21 which are not covered with the solder resist layer 24 become device connection terminals 25. Portions of the wiring pattern 21 which correspond to the through-holes 23 become external connection terminals 26 for connecting the electronic device to external wiring (not shown). In the present embodiment, the solder resist layer 24 is of a thermosetting type.

Electroplating, for example, is employed in order to form a plating layer 27 on each of the device connection terminals 25 and each of the external connection terminals 26. Examples of a material for the plating layer 27 include tin, solder, gold, and nickel-gold. The present embodiment uses nickel-gold.

While being transported, the film carrier tape for mounting electronic devices 20 is mounted with electronic devices such as IC chips or printed circuit boards. Notably, electronic devices are mounted on the corresponding solder resist layers 24 of the film carrier tape 20.

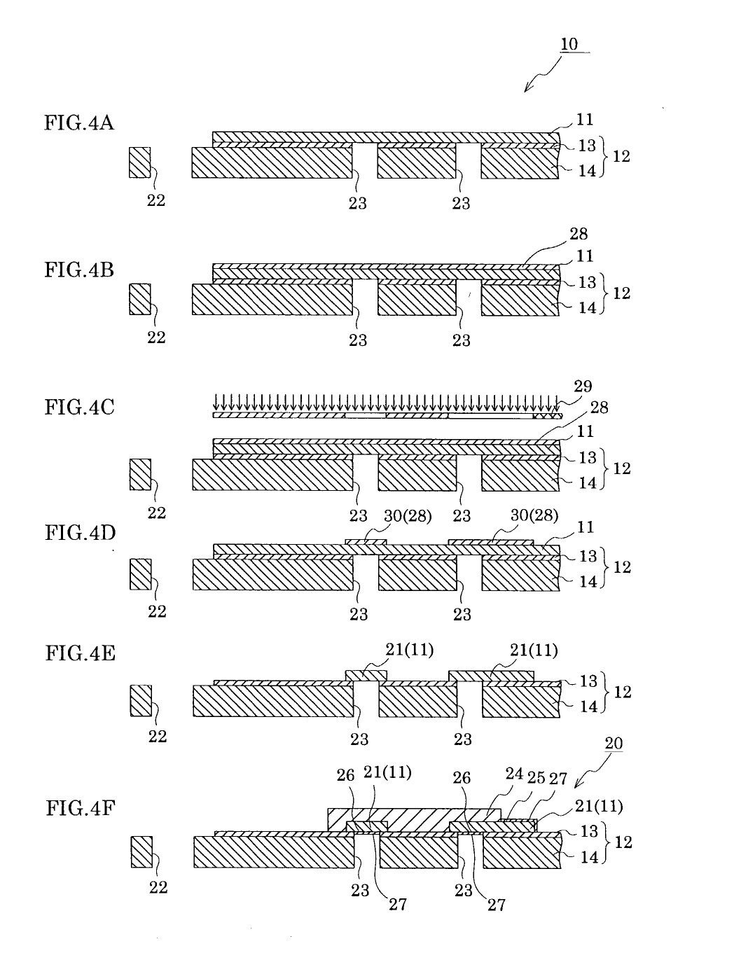

An example method for manufacturing the above-described film carrier tape for mounting electronic devices 20 will next be described with reference to FIG. 4. FIGS. 4A to 4F show an example method for manufacturing the film carrier tape 20.

First, as shown in FIG. 4A, the laminate film for mounting electronic devices 10 of the present invention is prepared. The laminate film 10 is manufactured by the steps of, for example, forming simultaneously the sprocket holes 22 extending through the insulating film 14 and the through-holes 23 extending through the insulating film 14 and the adhesive layer 13 by, for example, punching; and thermocompression-bonding the adhesive layer 13 and the insulating film 14 to the conductive layer 11 formed of copper foil, to thereby form the insulating layer 12. Notably, opposite side edge regions of the insulating layer 12 where the through-holes 23 are formed are not covered with the conductive layer 11.

Next, as shown in FIG. 4B, for example, a negative photoresist solution is applied by means of a general photolithography process to a region of the conductive layer 11 where the wiring patterns 21 are to be formed, thereby forming a photoresist layer 28. Needless to say, a positive photoresist solution may be used.

Positioning pins (not shown) are fitted into the corresponding sprocket holes 22 to thereby position the conductive layer 11 and the insulating layer 12. Subsequently, as shown in FIG. 4C, the photoresist layer 28 is exposed through a photomask 29 and then developed, whereby the photoresist layer 28 is patterned to form resist patterns 30, as shown in FIG. 4D, which will be used for forming wiring patterns.

Next, while the resist patterns 30 for wiring pattenrs serve as mask patterns, the conductive layer 11 is etched away by use of an etchant, thereby forming the wiring patterns 21 as shown in FIG. 4E. Subsequently, as shown in FIG. 4F, for example, a thermosetting solder resist solution is applied by means of a screen printing process, thereby forming the solder resist layer 24. Notably, the solder resist layer 24 may be formed by means of a general photolithography process in place of the screen printing process.

Subsequently, the plating layer 27 is formed by electroplating on each of the device connection terminals 25 and each of the external connection terminals 26. The plating layer 27 may be formed of any one of the above-mentioned materials, and a material for the plating layer 27 may be selected as adequate according to the manner of mounting of an electronic device.

The film carrier tape for mounting electronic devices 20 manufactured by used of the laminate film for mounting electronic devices 10 of the present invention is not limited to the above-described CSP-type film carrier tape. Needless to say, the film carrier tape 20 can be, for example, a COF-type, a BGA-type, or a μ-BGA-type film carrier tape.

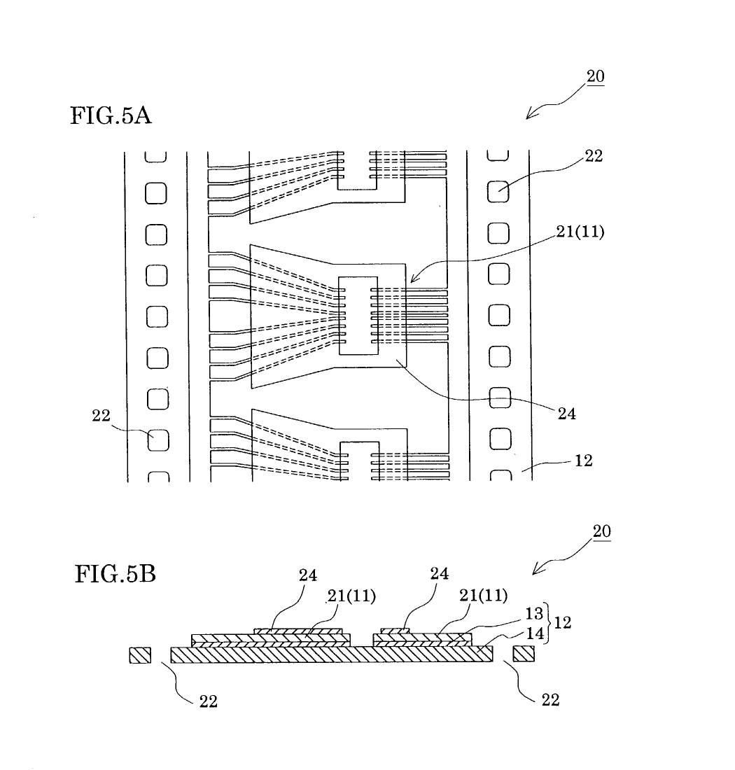

Next will be described a film carrier tape for mounting electronic devices according to another embodiment of the present invention manufactured from the above-described laminate film for mounting electronic devices 10. FIGS. 5A and 5B schematically show the structure of this film carrier tape, wherein FIG. 5A is a plan view of the film carrier tape, and FIG. 5B is a partially sectional view of the film carrier tape.

As shown in FIGS. 5A and 5B, the film carrier tape for mounting electronic devices 20 is manufactured from the above-described laminate film for mounting electronic devices 10 and is a chip on film (COF)-type film carrier tape for mounting directly bare IC chips at high density in small space. The film carrier tape 20 includes a plurality of wiring patterns 21 formed through patterning of the conductive layer 11 and a plurality of sprocket holes 22 formed on widthwise opposite sides of a region where the wiring patterns 21 are formed. Each of the wiring patterns 21 has a size substantially corresponding to that of an electronic device to-be mounted, and the wiring patterns 21 are provided in series on the insulating layer 12. The solder resist layer 24 is formed on each of the wiring patterns 21 by applying a solder resist solution to the wiring pattern 21 by means of a screen printing process. Notably, the solder resist layer 24 may be formed by means of a photolithography process in place of the screen printing process.

While being transported, the film carrier tape for mounting electronic devices 20 is mounted with electronic devices such as IC chips or printed circuit boards.

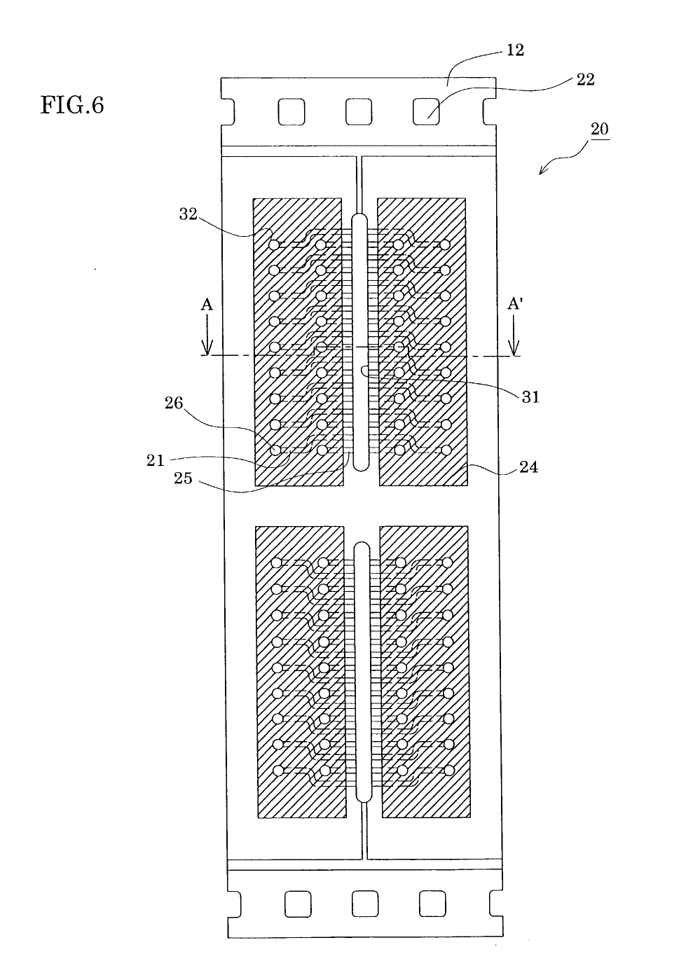

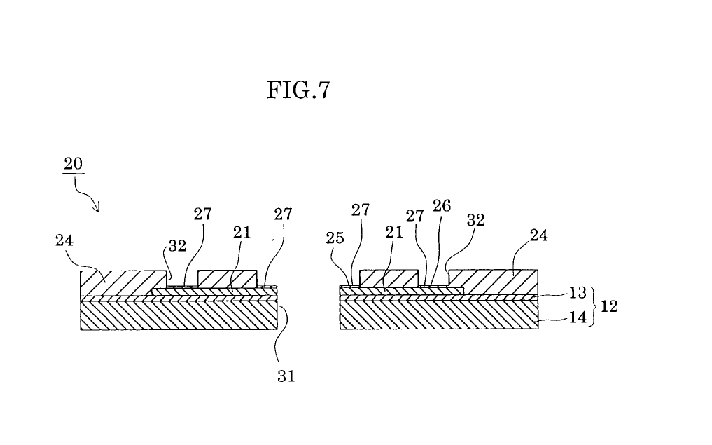

A film carrier tape for mounting electronic devices according to a further embodiment of the present invention manufactured from the above-described laminate film for mounting electronic devices 10 will next be described with reference to FIGS. 6 and 7. FIG. 6 is a schematic plan view of this film carrier tape, and FIG. 7 is a sectional view taken along line A-A′ of FIG. 6.

As shown in FIGS. 6 and 7, the film carrier tape for mounting electronic devices 20 is a TAB tape having wiring bonding slits 31 formed therein. A plurality of regions where corresponding electronic devices are to be mounted are provided in series on the insulating film 14. The sprocket holes 22 are formed at regular intervals at widthwise opposite side portions of the insulating film 14. The sprocket holes 22 are used to feed the film carrier tape 20 in the course of mounting electronic devices on the tape 20.

In this film carrier tape for mounting electronic devices 20, the wiring pattern 21, the device connection terminals 25, and the external connection terminals 26 are provided on substantially the entire surface of a portion of the insulating film 14 which is substantially as large as an electronic device to be mounted. The slit 31 is provided in order to establish connection between the device connection terminals 25 and an electronic device mounted on the reverse side of the device connection terminals 25.

A portion of each wiring pattern 21 which excludes the device connection terminals 25 and the external connection terminals 26 is covered with the solder resist layer 24. Terminal holes 32 are formed in the solder resist layer 24 at positions corresponding to the external connection terminals 26. The external connection terminals 26 serve as solder ball pads and are connected to an external device via solder balls (not shown). Exposed portions of each wiring pattern 21; i.e., the device connection terminals 25 and the external connection terminals 26 are covered with the plating layer 27. Preferably, in view of mounting through wire bonding, the plating layer 27 is formed by nickel-gold plating. However, the present invention is not limited thereto. For example, tin plating, solder plating, or gold plating may be selected as adequate according to the manner of mounting of an electronic device.

The film carrier tape for mounting electronic devices 20 manufactured from the laminate film for mounting electronic devices 10 of the present invention is relatively flat, and thus does not involve a problem such as defective transport or defective positioning in the course of mounting electronic devices thereon, thereby allowing electronic devices to be reliably mounted thereon at respectively predetermined positions.

The following examples are given to illustrate specific examples of the film carrier tape for mounting electronic devices 20 manufactured from the laminate film for mounting electronic devices 10 of the present invention. However, the present invention is not limited thereto.

### EXAMPLES

### Example 1

A copper foil having a coefficient of thermal expansion of 16.5 ppm/° C. and a thickness of 25 μm, which serves as the conductive layer 11, and a polyimide film having a coefficient of thermal expansion of 20.5 ppm/° C. along the width direction thereof and a thickness of 50 μm, which serves as the insulating film 14, were thermocompression-bonded via the adhesive layer 13 formed of a thermosetting polyamide resin and having a thickness of 12 μm, thereby obtaining the laminate film for mounting electronic devices 10. By use of the thus-obtained laminate film 10, a film carrier tape for mounting electronic devices of Example 1 was manufactured.

The coefficient of thermal expansion of the insulating film 14 was measured by the thermo-mechanical analysis (TMA) tension loading method described below.

Specifically, a polyimide film sample measuring 50 mm×50 mm was placed in a thermostatic oven maintained at 300±° C. for 30 minutes in a free contraction state. Then, the polyimide film sample was set on a thermo-mechanical analyzer (TMA) and was heated to 200° C. at a temperature rise rate of 20° C./min while being subjected to a load of 2 g. Then, a dimensional change of the polyimide film sample was measured. By use of the measured value, the coefficient of thermal expansion of the insulating film 14 was calculated by the following formula.

Coefficient of thermal expansion(CTE)α(ppm/° C.)=(L₁−L₀)/L₀(T₁−T₀)

where

L₀: length (mm) of polyimide film at T₀ (° C.)

L₁: length (mm) of polyimide film at T₁ (° C.)

T₀: temperature (° C.) at the beginning of a section for obtaining coefficient of thermal expansion

T₁: temperature (° C.) at the end of the section for obtaining coefficient of thermal expansion

The coefficient of thermal expansion of the conductive layer 11 was measured in the following manner. The conductive layer 11 was cut to obtain a sample having a width of 5.0 cm and a length of 25 cm. The sample was set in a commercially available thermal expansion measuring apparatus (DILATRONIC I, trade name of product of Tokyo Kogyo Co., Ltd.) and was held in a nitrogen atmosphere at a temperature rise rate of 2-5° C./min for 5-60 min. Then, a dimensional change of the sample was measured. By use of the measured value, the coefficient of thermal expansion of the copper foil was calculated.

### Example 2

A film carrier tape for mounting electronic devices was manufactured in a manner similar to that of Example 1 except that a polyimide film having a coefficient of thermal expansion of 19.3 ppm/° C. along the width direction thereof was used.

### Comparative Example 1

A film carrier tape for mounting electronic devices was manufactured in a manner similar to that of Example 1 except that a polyimide film having a coefficient of thermal expansion of 12.4 ppm/° C. along the width direction thereof was used.

### Comparative Example 2

A film carrier tape for mounting electronic devices was manufactured in a manner similar to that of Example 1 except that a polyimide film having a coefficient of thermal expansion of 15.4 ppm/° C. along the width direction thereof was used.

### Test Example

The conductive layer 11 of each of the laminate films for mounting electronic devices 10 was patterned through etching to form the wiring patterns 21. Subsequently, the film carrier tapes for mounting electronic devices were measured for warpage (mm). The solder resist layer 24, and a thickness of 5 to 15 μm, which was formed on a region of each of the wiring patterns 21 which excludes the device connection terminals 25 and the external connection terminals 26. Then, the device connection terminals 25 and the external connection terminals 26 were plated with gold. Subsequently, the film carrier tapes were measured for warpage (mm). The results are shown in Table 1.

Notably, the warpage (mm) of each of the film carrier tapes for mounting electronic devices along the width direction was measured in the following manner. Each of the film carrier tapes was cut to obtain a strip having a length of 190 mm and a width of 48 mm. The strips were adjusted such that the polyimide films thereof were saturated at 23° C. and 55%RH (relative humidity). Then, warpage of the strips were measured.

Warpage (mm) was defined in the following manner. One longitudinal side edge portion of the strip was fixed on a bench surface by use of an adhesive tape with the conductive layer 11 facing upward. The height (mm) of the other longitudinal side edge above the bench surface was defined as warpage (mm).

TABLE 1

| | | coefficient of | | |
|---|---|---|---|---|
| | coefficient of | Thermal | | |
| | Thermal | expansion | Warpage (mm) | |
| | expansion | along | After | |
| | along width | longitudinal | forming | |
| | direction | direction | wiring | After gold |
| | (ppm/° C.) | (ppm/° C.) | patterns | plating |
| Example 1 | 20.5 | 15.8 | 4.4 | 14.6 |
| Example 2 | 19.3 | 12.0 | 1.9 | 17.7 |
| Comp. | 12.4 | 13.0 | 8.3 | 18.4 |
| Example 1 | | | | |
| Comp. | 15.4 | 13.8 | 6.3 | 18.2 |
| Example 2 | | | | |

As shown in Table 1, Examples 1 and 2, which use a polyimide film having a coefficient of thermal expansion along the width direction thereof higher than that (16.5 ppm/° C.) of the copper foil, exhibit a small amount of warpage (mm) as compared with Comparative Examples 1 and 2, which use a polyimide film having a coefficient of thermal expansion along the width direction thereof lower than that of the copper foil.

As described above, in the laminate film for mounting electronic devices and the film carrier tape for mounting electronic devices according to the present invention, since the coefficient of thermal expansion of the insulating film along the width direction of the insulating film is made substantially equal to or higher than that of the conductive layer along the width direction of the conductive layer, warpage along the width direction of the laminate film and the film carrier tape can be reduced easily and effectively. Therefore, problems such as defective transport do not occur in the course of mounting electronic devices, and electronic devices can be reliably mounted at predetermined positions.

What is claimed is:

1. A laminate film for mounting electronic devices, comprising a conductive layer and an insulating film bonded through thermocompression bonding, a coefficient of thermal expansion of the insulating film along a width direction of the insulating film being substantially equal to or higher than that of the conductive layer along a width direction of the conductive layer.

2. A laminate film for mounting electronic devices according to claim 1, wherein the coefficient of thermal expansion of the insulating film along the width direction of the insulating film is 16.0 to 30.0 ppm/° C.

3. A laminate film for mounting electronic devices according to claim 2, wherein the conductive layer is a copper foil.

4. A laminate film for mounting electronic devices according to any one of claims 1 to 3, wherein the insulating film and the conductive layer are bonded through thermocompression bonding via a thermoplastic resin layer.

5. A laminate film for mounting electronic devices according to any one of claims 1 to 3, wherein the insulating film and the conductive layer are bonded through thermocompression bonding via a thermosetting resin layer.

6. A film carrier tape for mounting electronic devices, comprising a laminate film for mounting electronic devices as described in any one of claims 1 to 3.

7. A film carrier tape for mounting electronic devices, comprising a laminate film for mounting electronic devices as described in claim 4.

8. A film carrier tape for mounting electronic devices, comprising a laminate film for mounting electronic devices as described in claim 5.
